(19) United States
(12) Patent Application Publication
(10) Pub. No.: US 2025/0311634 A1
(43) Pub. Date: Oct. 2, 2025

(54) PIEZOELECTRIC ELEMENT, LIQUID EJECTION HEAD, AND PRINTER

(71) Applicant: SEIKO EPSON CORPORATION, Tokyo (JP)

(72) Inventors: Daisuke NAGANO, MATSUMOTO-SHI (JP); Yasuhiro HORIBA, SAPPORO-SHI (JP)

(21) Appl. No.: 19/091,251

(22) Filed: Mar. 26, 2025

(30) Foreign Application Priority Data
Mar. 28, 2024 (JP) 2024-053429

(51) Int. Cl. H10N 30/88; B41J 2/14; H10N 30/00; H10N 30/853; H10N 30/87

(52) U.S. Cl. CPC H10N 30/883; B41J 2/14233; B41J 2/1433; H10N 30/704; H10N 30/8542; H10N 30/872; B41J 2002/14491

(57) ABSTRACT

A piezoelectric element includes: a first electrode provided above a substrate; a piezoelectric layer provided above the first electrode; a second electrode provided above the piezoelectric layer; and a moisture-resistant layer covering at least a part of the piezoelectric layer, and when secondary ion mass spectrometry is performed on the piezoelectric layer, a hydrogen concentration calculated based on an integrated intensity in a range of 50 nm or more and 300 nm or less from a surface of the piezoelectric layer is 1.50×10¹⁵ atom/cm² or less.

The present application is based on, and claims priority from JP Application Serial Number 2024-053429, filed Mar. 28, 2024, the disclosure of which is hereby incorporated by reference herein in its entirety.

### BACKGROUND

### 1. Technical Field

The present disclosure relates to a piezoelectric element, a liquid ejection head, and a printer.

### 2. Related Art

A piezoelectric element used in a liquid ejection head or the like of an inkjet printer is implemented by, for example, sandwiching a piezoelectric layer made of a piezoelectric material having an electromechanical conversion function between two electrodes.

For example, JP-A-2022-65018 discloses a piezoelectric thin film element including a lower electrode film, a piezoelectric thin film formed in a lower electrode film shape and containing potassium, sodium, and niobium, and an upper electrode film formed on the piezoelectric thin film.

In the piezoelectric thin film element as described above, it is required to improve moisture resistance while ensuring insulation properties of the piezoelectric thin film.

### SUMMARY

A piezoelectric element according to an aspect of the present disclosure includes: a first electrode provided above a substrate; a piezoelectric layer provided above the first electrode; a second electrode provided above the piezoelectric layer; and a moisture-resistant layer covering at least a part of the piezoelectric layer, and when secondary ion mass spectrometry is performed on the piezoelectric layer, a hydrogen concentration calculated based on an integrated intensity in a range of 50 nm or more and 300 nm or less from a surface of the piezoelectric layer is 1.50×10¹⁵ atom/cm² or less.

A liquid ejection head according to an aspect of the present disclosure includes: the piezoelectric element; and a nozzle plate in which a nozzle hole is formed, in which the substrate has a channel formation substrate in which a pressure generation chamber whose volume is changed by the piezoelectric element is formed, and the nozzle hole communicates with the pressure generation chamber.

A printer according to an aspect of the present disclosure includes: the liquid ejection head; a conveyance mechanism configured to move a recorded medium relative to the liquid ejection head; and a control unit configured to control liquid ejection head and the conveyance mechanism.

### BRIEF DESCRIPTION OF THE DRAWINGS

FIG. 1 is a plan view schematically showing a piezoelectric element according to an embodiment.

FIG. 2 is a cross-sectional view schematically showing the piezoelectric element according to the embodiment.

FIG. 3 is a cross-sectional view schematically showing the piezoelectric element according to the embodiment.

FIG. 4 is a cross-sectional view schematically showing a producing process of the piezoelectric element according to the embodiment.

FIG. 5 is a cross-sectional view schematically showing a producing process of the piezoelectric element according to the embodiment.

FIG. 6 is a cross-sectional view schematically showing a producing process of the piezoelectric element according to the embodiment.

FIG. 7 is a cross-sectional view schematically showing a piezoelectric element according to a reference example.

FIG. 8 is a cross-sectional view schematically showing a piezoelectric element according to a reference example.

FIG. 9 is a cross-sectional view schematically showing a piezoelectric element according to a reference example.

FIG. 10 is a cross-sectional view schematically showing the piezoelectric element according to the embodiment.

FIG. 11 is an exploded perspective view schematically showing a liquid ejection head according to the embodiment.

FIG. 12 is a perspective view schematically showing a printer according to the embodiment.

FIG. 13 is a table showing results of SIMS and leak current measurement in Experimental Examples 1 to 3.

FIG. 14 is a graph showing results of the SIMS in Experimental Examples 1 to 3.

FIG. 15 is a graph showing results of the leak current measurement in Experimental Examples 1 to 3.

FIG. 16 is a table showing results of the SIMS in Experimental Examples 4 and 5.

FIG. 17 is a graph showing results of the SIMS in Experimental Examples 4 and 5.

FIG. 18 is a graph showing results of the SIMS in Experimental Examples 6 to 8.

FIG. 19 is a table showing experimental results in Experimental Examples 9 to 16.

FIG. 20 is a graph showing experimental results in Experimental Examples 9 to 16.

### DESCRIPTION OF EMBODIMENTS

Hereinafter, a preferred embodiment according to the present disclosure will be described in detail with reference to the drawings. The embodiment to be described below does not unduly limit contents of the present disclosure described in the claims. All the configurations to be described below are not necessarily essential elements of the present disclosure.

### 1. Piezoelectric Element

### 1.1. Configuration

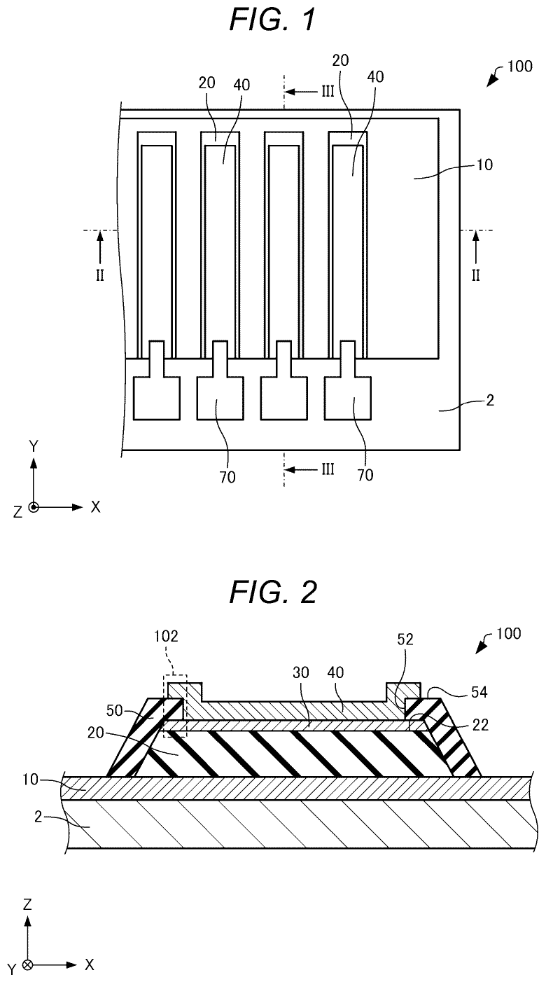

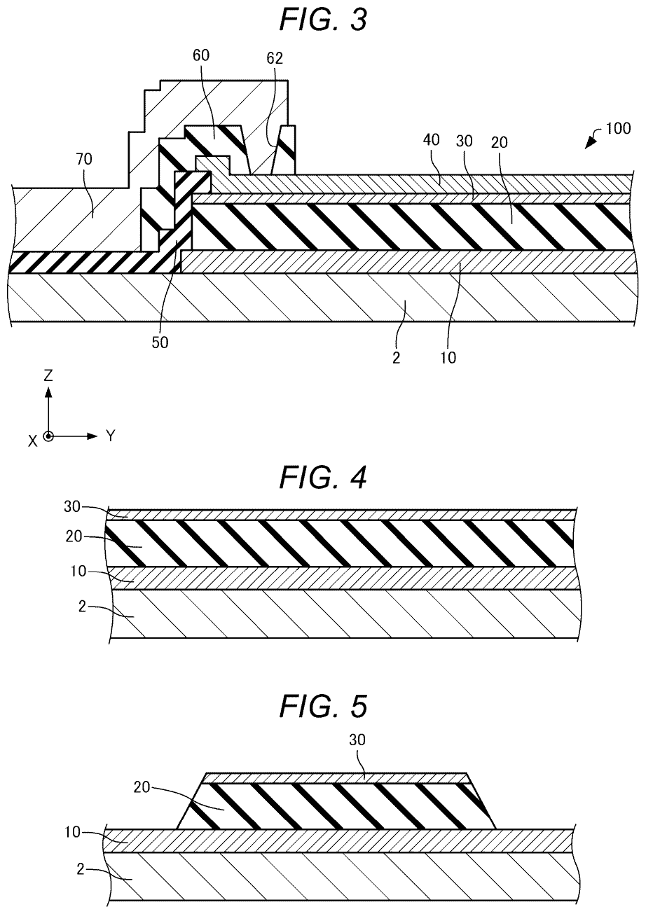

First, a piezoelectric element according to the embodiment will be described with reference to the drawings. FIG. 1 is a plan view schematically showing a piezoelectric element 100 according to the embodiment. FIG. 2 is a cross-sectional view taken line II-II in FIG. 1 along schematically showing the piezoelectric element 100 according to the embodiment. FIG. 3 is a cross-sectional view taken along line III-III in FIG. 1 schematically showing the piezoelectric element 100 according to the embodiment. FIGS. 1 to 3 show an X axis, a Y axis, and a Z axis as three axes orthogonal to one another.

As shown in FIGS. 1 to 3, the piezoelectric element 100 includes, for example, a first electrode 10, a piezoelectric layer 20, a second electrode 30, a third electrode 40, a moisture-resistant layer 50, an organic insulating layer 60, and an interconnect 70. For convenience, in FIG. 1, members other than a substrate 2, the first electrode 10, the piezoelectric layer 20, the third electrode 40, and the interconnect 70 are not illustrated.

The piezoelectric element 100 is provided on a substrate 2. In an example shown in FIG. 1, a plurality of piezoelectric elements 100 are provided. The number of the piezoelectric elements 100 is not particularly limited. In the example shown in FIG. 1, the plurality of piezoelectric elements 100 are arranged in an X-axis direction.

The substrate 2 is a flat plate formed of, for example, a semiconductor or an insulator. The substrate 2 may have a single layer structure or a layered structure in which a plurality of layers are stacked. An internal structure of the substrate 2 is not limited as long as an upper surface has a planar shape, and the substrate 2 may have a structure in which a space or the like is formed therein.

The substrate 2 may include a vibrating plate that is deformed by an action of the piezoelectric layer 20. The vibrating plate includes, for example, a silicon oxide layer, a zirconium oxide layer, or a layered structure in which a zirconium oxide layer is provided on a silicon oxide layer.

As shown in FIG. 2, the first electrode 10 is provided above the substrate 2. In the illustrated example, the first electrode 10 is provided on the substrate 2. In the description of the present disclosure, the term “above” is used as, for example, “a specific object (hereinafter referred to as “A”) is provided above another specific object (hereinafter referred to as “B”)”. Such a case includes a case where A is provided directly on B and a case where A is provided on B via another object.

The first electrode 10 is provided between the substrate 2 and the piezoelectric layer 20. The first electrode 10 has, for example, a layer shape. A thickness of the first electrode 10 is, for example, 5 nm or more and 500 nm or less, and preferably 10 nm or more and 300 nm or less. In adjacent piezoelectric elements 100, the first electrodes 10 are coupled to each other. The first electrode 10 constitutes a common electrode in the plurality of piezoelectric elements 100.

The first electrode 10 is, for example, a titanium layer, a platinum layer, or an iridium layer. The first electrode 10 may be a layered structure formed by sequential stacking of a titanium layer, a platinum layer, and an iridium layer from a substrate 2 side. The titanium layer increases, for example, adhesion between the substrate 2 and the platinum layer. The first electrode 10 is one electrode for applying a voltage to the piezoelectric layer 20.

The piezoelectric layer 20 is provided above the first electrode 10. In the illustrated example, the piezoelectric layer 20 is provided on the first electrode 10. The piezoelectric layer 20 is provided between the first electrode 10 and the second electrode 30. A thickness of the piezoelectric layer 20 is, for example, 100 nm or more and 3000 nm or less, and preferably 200 nm or more and 2500 nm or less. The piezoelectric layer 20 is deformed by application of a voltage between the first electrode 10 and the third electrode 40.

The piezoelectric layer 20 contains, for example, a complex oxide a perovskite type structure having containing potassium (K), sodium (Na), and niobium (Nb). The piezoelectric layer 20 is, for example, a potassium sodium niobate ((K,Na)NbO₃: KNN) layer. A composition of the perovskite type structure of the piezoelectric layer 20 may be a stoichiometric composition or may be different from the stoichiometric composition. The piezoelectric layer 20 may be a KNN layer with an additive. The additive includes, for example, lithium (Li), manganese (Mn), copper (Cu), and oxides thereof. A content of the additive in the piezoelectric layer 20 is, for example, 10 mol % or less, and preferably 5 mol % or less.

A material for the piezoelectric layer 20 is not limited to the KNN. The piezoelectric layer 20 may contain a complex oxide having a perovskite type structure containing lead (Pb), zirconium (Zr), and titanium (Ti). The material for the piezoelectric layer 20 may be lead zirconate titanate (Pb(Zr,Ti)O₃: PZT)).

The second electrode 30 is provided above the piezoelectric layer 20. In the illustrated example, the second electrode 30 is provided on the piezoelectric layer 20. The second electrode 30 is provided between the piezoelectric layer 20 and the third electrode 40. The second electrode 30 has, for example, a layer shape. A thickness of the second electrode 30 is, for example, less than a thickness of the third electrode 40. The thickness of the second electrode 30 is, for example, 1 nm or more and 100 nm or less, and preferably 5 nm or more and 50 nm or less.

A material for the second electrode 30 is, for example, a metal oxide. The second electrode 30 is conductive. The second electrode 30 is, for example, iridium oxide (IrO₂) or ruthenium oxide (RuO₂).

The third electrode 40 is provided above the second electrode 30. In the illustrated example, the third electrode 40 is provided on the second electrode 30. The third electrode 40 is electrically coupled to the second electrode 30. The third electrode 40 has, for example, a layer shape. The thickness of the third electrode 40 is, for example, 5 nm or more and 500 nm or less, and preferably 10 nm or more and 300 nm or less. In adjacent piezoelectric elements 100, the third electrodes 40 are spaced apart from each other. The third electrode 40 constitutes an individual electrode in the plurality of piezoelectric elements 100.

Electrical resistivity of the third electrode 40 is lower than electrical resistivity of the second electrode 30. A material for the third electrode 40 is, for example, a noble metal. The third electrode 40 is, for example, a platinum layer or an iridium layer. The third electrode 40 may be formed by stacking of a plurality of layers exemplified above. The second electrode 30 and the third electrode 40 are the other electrodes for applying a voltage to the piezoelectric layer 20.

The moisture-resistant layer 50 covers at least a portion of the piezoelectric layer 20. In the illustrated example, the moisture-resistant layer 50 covers a side surface of the piezoelectric layer 20. The moisture-resistant layer 50 is provided on the second electrode 30 and the first electrode 10. A first contact hole 52 is formed in the moisture-resistant layer 50. The first contact hole 52 exposes the second electrode 30. The third electrode 40 is provided in the first contact hole 52. The piezoelectric element 100 has a stacked portion 102 in which the second electrode 30, the moisture-resistant layer 50, and the third electrode 40 are stacked in this order from a piezoelectric layer 20 side. In the stacked portion 102, the moisture-resistant layer 50 is provided between the second electrode 30 and the third electrode 40.

A thickness of the moisture-resistant layer 50 is, for example, 5 nm or more and 100 nm or less, and preferably 10 nm or more and 70 nm or less. A thickness of the layer in the piezoelectric element 100 such as the thickness of the moisture-resistant layer 50 is measured by, for example, a scanning electron microscope (SEM).

A material for the moisture-resistant layer 50

is, for example, a metal oxide. The moisture-resistant layer 50 is, for example, a hafnium oxide (HfO₂) layer, a thallium oxide (Ta₂O₅) layer, a niobium oxide (Nb₂O₅) layer, a zirconium oxide (ZrO₂) layer, or a titanium oxide (TiO₂) layer. The moisture-resistant layer 50 has a function of reducing moisture entering the piezoelectric layer 20.

As shown in FIG. 3, the organic insulating layer 60 is provided on the third electrode 40 and the moisture-resistant layer 50. The organic insulating layer 60 covers the moisture-resistant layer 50. In the organic insulating layer 60, a second contact hole 62 is formed in the organic insulating layer 60. The second contact hole 62 exposes the third electrode 40. A material for the organic insulating layer 60 is, for example, a resist. The material for the organic insulating layer 60 may be a permanent resist.

The interconnect 70 is provided on the moisture-resistant layer 50, on the organic insulating layer 60, and in the second contact hole 62. The interconnect 70 is electrically coupled to the third electrode 40. A material for the interconnect 70 is, for example, gold.

### 1.2. SIMS

When secondary ion mass spectrometry (SIMS) is performed on the piezoelectric layer 20, a hydrogen concentration calculated based on an integrated intensity in a range of 50 nm or more and 300 nm or less from a surface 22 of the piezoelectric layer 20 (hereinafter, also referred to as an “integrated hydrogen concentration”) is 1.50×10¹⁵ atom/cm² or less, preferably 1.00×10¹⁵ atom/cm² or less, and more preferably 9.75×10¹⁴ atom/cm² or less. The integrated hydrogen concentration in the piezoelectric layer 20 is, for example, 1.00×10¹⁴ atom/cm² or more, preferably 5.00×10¹⁴ atom/cm² or more, and more preferably 8.72×10¹⁴ atom/cm² or more.

The surface 22 of the piezoelectric layer 20 is an upper surface of the piezoelectric layer 20 and is a surface of the piezoelectric layer 20 on a second electrode 30 side. In the example shown in FIG. 2, the surface 22 is in contact with the second electrode 30. In the SIMS, the piezoelectric layer 20 is irradiated with an ion beam, and the integrated hydrogen concentration is calculated based on a detected intensity. In the SIMS, analysis in a thickness direction of the piezoelectric layer 20 can be performed. Hereinafter, a method of converting the intensity detected by the SIMS into the concentration will be described in order.
(1) An object to be subjected to concentration conversion and a reference object having a similar structure as the object are prepared.
(2) An element whose concentration is to be defined is ion-implanted into the prepared reference object.
(3) Based on understood information (thickness, composition, density) of the object, simulation is performed in advance, and ion implantation conditions (acceleration voltage, current, processing time) are determined such that a specified maximum concentration is obtained at a specified position in a thickness direction. For example, when a position in the thickness direction is too close to a surface, an influence of contamination is likely to occur, and when the position is too deep, extra ions are implanted into a lower layer of a target layer.
(4) implantation is performed on the reference object under the determined conditions, and a dose amount (ion implantation amount) is calculated based on a current value, a processing time, and an ion beam irradiation area at that time.
(5) The reference object (with and without ion implantation) is measured with similar SIMS apparatus and under similar measurement conditions as those for measuring the object to be subjected to concentration conversion.
(6) A peak intensity of the reference object without the ion implantation is subtracted from a peak intensity of the reference object with the ion implantation, and an integrated value of a parent phase range is calculated. A relationship between the integrated value and the dose amount is a relative sensitivity factor (RSF).
(7) Using the obtained relative sensitivity factor, an entire secondary ion intensity profile of a measurement result of the object to be subjected to concentration conversion is converted into concentration.

As described above, the intensity detected by the SIMS can be converted into concentration.

When the piezoelectric element 100 is exposed to an atmosphere having a temperature of 80° C. and a humidity of 100% for 24 hours and then the SIMS is performed on the moisture-resistant layer 50, for example, a hydrogen concentration at a distance of 22 nm or less from a surface 54 of the moisture-resistant layer 50 is 1/10 of a concentration in the surface 54 of the moisture-resistant layer 50. In the illustrated example, the surface 54 of the moisture-resistant layer 50 is an upper surface of the moisture-resistant layer 50.

### 1.3. Production Method

Next, a method of producing the piezoelectric element 100 according to the embodiment will be described with reference to the drawings. FIGS. 4 to 6 are cross-sectional views schematically showing a producing process of the piezoelectric element 100 according to the embodiment.

As shown in FIG. 4, the substrate 2 is prepared. Specifically, a silicon oxide layer is formed by thermal oxidation of a silicon substrate. Then, a zirconium layer is formed on the silicon oxide layer by sputtering or the like, and the zirconium layer is thermally oxidized and a zirconium oxide layer is formed. The substrate 2 can be prepared in the above-described process.

Then, the first electrode 10 is formed on the substrate 2. The first electrode 10 is formed by, for example, sputtering or vacuum deposition.

Then, the piezoelectric layer 20 is formed on the first electrode 10. The piezoelectric layer 20 may be formed by, for example, a liquid phase method such as a sol-gel method or a metal organic deposition (MOD) method, or a gas phase method such as sputtering. Hereinafter, a case where the piezoelectric layer 20 that is a KNN layer is formed by a liquid phase method will be described.

First, a metal complex containing potassium, a metal complex containing sodium, and a metal complex containing niobium are dissolved or dispersed in an organic solvent to prepare a precursor solution. For example, the metal complex containing potassium includes potassium 2-ethylhexanoate. For example, the metal complex containing sodium includes sodium 2-ethylhexanoate. The metal complex containing niobium includes niobium 2-ethylhexanoate. For example, the organic solvent includes 2-ethylhexanoic acid, decane, and a mixed solvent thereof.

Then, the prepared precursor solution is applied onto the first electrode 10 by using spin coating or the like to form a precursor layer. Then, the precursor layer is heated, for example, at 130° C. or higher and 250° C. or lower and dried for a certain period of time, and the dried precursor layer is further heated, for example, at 300° C. or higher and 450° C. or lower and held for a certain period of time to be degreased. Then, the degreased precursor layer is fired to be crystallized.

In this manner, a crystal layer can be formed. The above series of processes from the application of the precursor solution to the firing of the precursor layer are repeated a plurality of times. Thereby, the piezoelectric layer 20 including a plurality of crystal layers can be formed.

In forming the piezoelectric layer 20, a heating device used for drying and degreasing the precursor layer is, for example, a hot plate. A heating device used for firing the precursor layer is, for example, an infrared lamp annealing device using rapid thermal annealing (RTA).

Then, the second electrode 30 is formed on the piezoelectric layer 20. The second electrode 30 is formed by, for example, a chemical vapor deposition (CVD) or sputtering.

As shown in FIG. 5, the second electrode 30 and the piezoelectric layer 20 are patterned. The patterning is performed by, for example, photolithography and etching. As the etching, for example, ion milling is used.

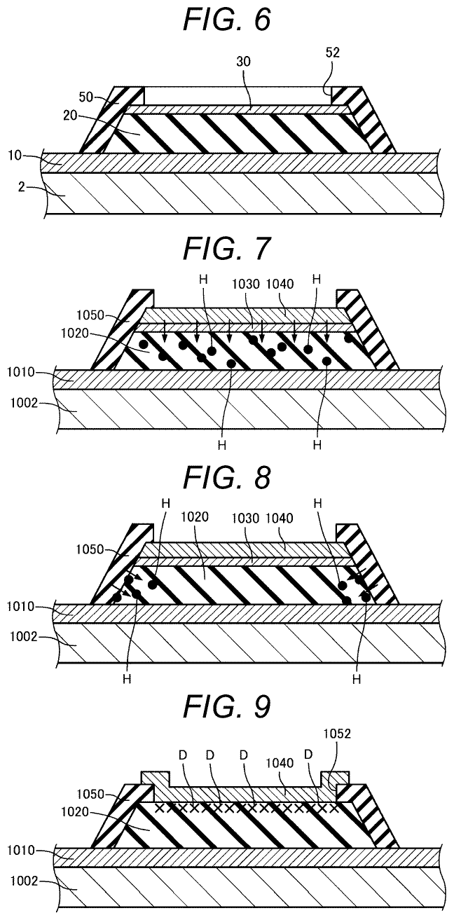

As shown in FIG. 6, the moisture-resistant layer 50 covering the piezoelectric layer 20 and the second electrode 30 is formed. The moisture-resistant layer 50 is formed by, for example, an atomic layer deposition (ALD) method. In the ALD method, it is known that when a film is formed at about 85° C., a dense layer can be formed if water (H₂O) is used as an oxidizing agent, and when a film is formed at about 150° C., a dense layer can be formed if ozone (O₃) is used as the oxidizing agent. The moisture-resistant layer 50 may be a layer formed by the ALD method using H₂O as the oxidizing agent, or may be a layer formed by the ALD method using O₃ as the oxidizing agent.

Then, the moisture-resistant layer 50 is patterned to form the first contact hole 52. The second electrode 30 is exposed by the first contact hole 52. The patterning is performed by, for example, photolithography and etching.

As shown in FIG. 2, the third electrode 40 is formed on the second electrode 30 and the moisture-resistant layer 50. The third electrode 40 is formed by, for example, sputtering or vacuum deposition. Then, the third electrode 40 is patterned. The patterning is performed by, for example, photolithography and etching.

As shown in FIG. 3, the organic insulating layer 60 in which the second contact hole 62 is formed is formed on the third electrode 40 and the moisture-resistant layer 50. The organic insulating layer 60 is formed by performing film formation by a spin coating, drying, exposure, and development, and then performing curing by heat treatment. The heat treatment may be performed in air or in vacuum.

Then, the interconnect 70 is formed on the third electrode 40, the moisture-resistant layer 50, and the organic insulating layer 60. The interconnect 70 is formed by, for example, film formation by a sputtering and patterning by photolithography and etching.

The piezoelectric element 100 can be produced in the above-described process.

### 1.4. Functions and Effects

The piezoelectric element 100 includes the first electrode 10 provided above the substrate 2, the piezoelectric layer 20 provided above the first electrode 10, the second electrode 30 provided above the piezoelectric layer 20, and the moisture-resistant layer 50 covering at least a portion of the piezoelectric layer 20. When secondary ion mass spectrometry is performed on the piezoelectric layer 20, an integrated hydrogen concentration calculated based on an integrated intensity in a range of 50 nm or more and 300 nm or less from the surface 22 of the piezoelectric layer 20 is 1.50×10¹⁵ atom/cm² or less.

Therefore, in the piezoelectric element 100, insulation properties of the piezoelectric layer 20 can be enhanced as compared with a case where the integrated hydrogen concentration in the piezoelectric layer is larger than 1.50×10¹⁵ atom/cm². When the integrated hydrogen concentration in the piezoelectric layer is high, a part of the complex oxide forming the piezoelectric layer is reduced, the insulation properties deteriorate, and a leak current increases. Further, in the piezoelectric element 100, moisture entering the piezoelectric layer 20 can be prevented by the moisture-resistant layer 50.

Here, FIG. 7 is a cross-sectional view schematically showing a piezoelectric element according to a reference example. The piezoelectric element according to the reference example is implemented by forming a first electrode 1010, a piezoelectric layer 1020, a second electrode 1030, and a third electrode 1040 in this order on/above the substrate 1002, patterning each layer, and then forming a moisture-resistant layer 1050.

When the moisture-resistant layer 1050 is formed by an ALD method using O₃ as an oxidizing agent at a film formation temperature of 150° C., as shown in FIG. 7, hydrogen (H) taken into the third electrode 40 during producing diffuses into the piezoelectric layer 1020 due to a temperature during film formation of the moisture-resistant layer 1050. Therefore, a hydrogen concentration in the piezoelectric layer 1020 increases, and a leak current increases.

When the moisture-resistant layer 1050 is formed by an ALD method using H₂O as an oxidizing agent at a film formation temperature of 85° C., as shown in FIG. 8, hydrogen (H) from H₂O of the oxidizing agent diffuses into the piezoelectric layer 1020 during film formation of moisture-resistant layer 1050. Therefore, the hydrogen concentration in the piezoelectric layer 1020 increases, and a leak current increases.

Thus, in the example shown in FIGS. 7 and 8, by forming the moisture-resistant layer 1050, the hydrogen concentration in the piezoelectric layer 1020 increases, and insulation properties deteriorates.

On the other hand, as shown in FIG. 9, when the second electrode 1030 is not formed, but the moisture-resistant layer 1050 covering the piezoelectric layer 1020 is formed, a contact hole 1052 is formed, and then the third electrode 1040 is formed, the piezoelectric layer 1020 is subjected to etching damage D and surface contamination when the contact hole 1052 is formed. Therefore, insulation properties deteriorate.

As described above, in the piezoelectric element 100, even when the moisture-resistant layer 50 is provided, the integrated hydrogen concentration in the piezoelectric layer 20 is as low as 1.50×10¹⁵ atom/cm² or less. Therefore, in the piezoelectric element 100, moisture resistance of the piezoelectric layer 20 can be improved while ensuring the insulation properties of the piezoelectric layer 20. As a result, the piezoelectric element 100 with low power consumption, high efficiency, and high reliability can be achieved.

In the piezoelectric element 100, the integrated hydrogen concentration in the piezoelectric layer 20 is preferably 1.00×10¹⁵ atom/cm² or less, and more preferably 9.75×10¹⁴ atom/cm² or less. Therefore, in the piezoelectric element 100, the insulation properties of the piezoelectric layer 20 can be further enhanced.

The piezoelectric element 100 includes the third electrode 40 provided above the second electrode 30 and electrically coupled to the second electrode 30, the material for the second electrode 30 is a metal oxide, and the material for the third electrode 40 is a noble metal. Therefore, in the piezoelectric element 100, resistance of an electrode including the second electrode 30 and the third electrode 40 can be reduced as compared with a case where the third electrode is not provided.

The piezoelectric element 100 includes the stacked portion 102 in which the second electrode 30, the moisture-resistant layer 50, and the third electrode 40 are stacked in this order from the piezoelectric layer 20 side. Therefore, in the piezoelectric element 100, the second electrode 30, the moisture-resistant layer 50, and the third electrode 40 are formed in this order from the piezoelectric layer 20 side. Therefore, the second electrode 30 can reduce etching damage or contamination to the piezoelectric layer 20 when the first contact hole 52 is formed. Thereby, it is possible to prevent a Schottky barrier at an interface between the piezoelectric layer 20 and the electrode from being lowered.

In the piezoelectric element 100, the moisture-resistant layer 50 is a layer formed by the ALD method using O₃ as the oxidizing agent. In the piezoelectric element 100, when O₃ is used as an oxidizing agent at a film formation temperature of about 150° C., the moisture-resistant layer 50 is formed before the third electrode 40 is formed, so that when the moisture-resistant layer 50 is formed, hydrogen taken into the third electrode 40 can be prevented from diffusing into the piezoelectric layer 20. Further, since the oxidizing agent does not contain hydrogen, reduction of the piezoelectric layer 20 by the oxidizing agent can be prevented.

In the piezoelectric element 100, the moisture-resistant layer 50 is a layer formed by the ALD method using H₂O as the oxidizing agent. Therefore, in the piezoelectric element 100, the dense moisture-resistant layer 50 can be formed even at a film formation temperature of about 85° C.

In the piezoelectric element 100, when the piezoelectric element 100 is exposed to an atmosphere having a temperature of 80° C. and a humidity of 100% for 24 hours and then the SIMS is performed on the moisture-resistant layer 50, a hydrogen concentration at a distance of 22 nm or less from a surface 54 of the moisture-resistant layer 50 is 1/10 of a concentration in the surface 54 of the moisture-resistant layer 50. Therefore, moisture resistance can be improved in the piezoelectric element 100.

In the piezoelectric element 100, the piezoelectric layer 20 includes a complex oxide having a perovskite type structure containing potassium, sodium, and niobium. In the piezoelectric element 100, the piezoelectric layer 20 does not contain lead, and is therefore environmentally friendly.

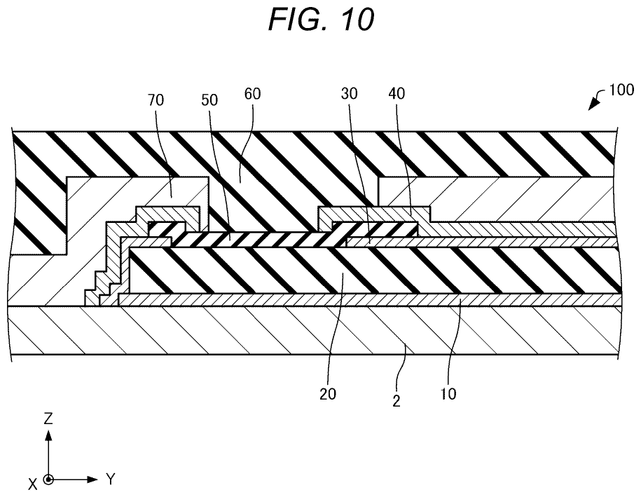

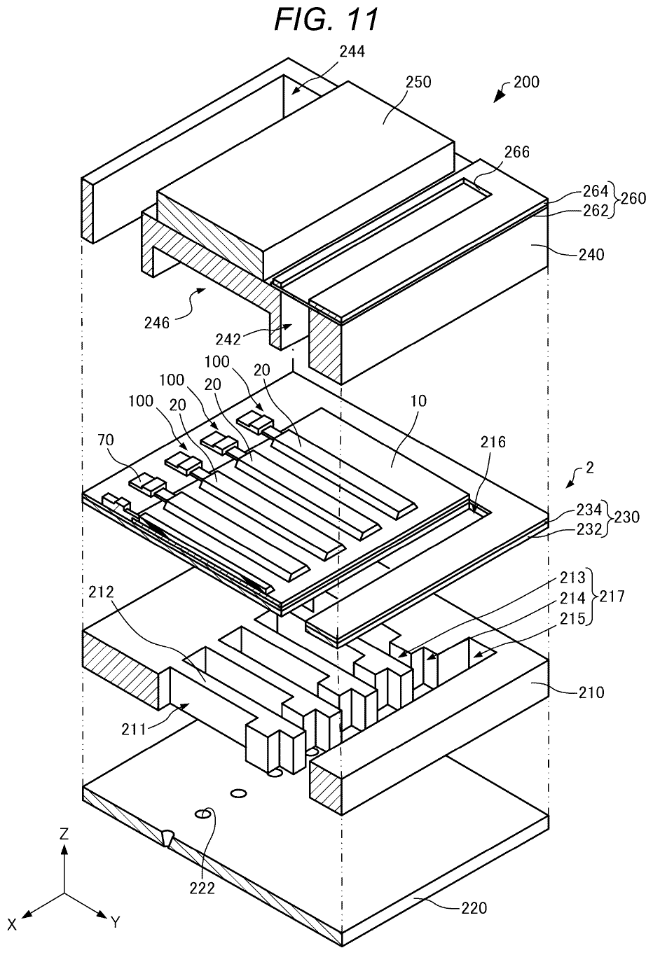

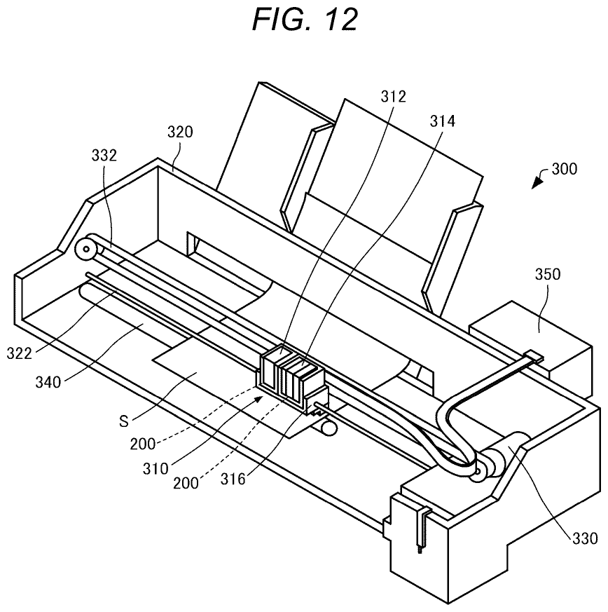

Although an example is described above in which the first electrode 10 is a common electrode and the third electrode 40 is an individual electrode, the first electrode 10 may be an individual electrode and the third electrode 40 may be a common electrode. For example, FIG. 10 is a cross-sectional view schematically showing an example in which the first electrode 10 is an individual electrode and the third electrode 40 is a common electrode.

### 2. Liquid Ejection Head

Next, a liquid ejection head according to the embodiment will be described with reference to the drawings. FIG. 11 is an exploded perspective view schematically showing a liquid ejection head 200 according to the embodiment.

As shown in FIG. 11, for example, the liquid ejection head 200 includes the substrate 2, the piezoelectric elements 100, a nozzle plate 220, a protective substrate 240, a circuit board 250, and a compliance substrate 260. The substrate 2 includes, for example, a channel formation substrate 210 and a vibrating plate 230.

The channel formation substrate 210 is, for example, a silicon substrate. Pressure generation chambers 211 are formed in the channel formation substrate 210. The pressure generation chambers 211 are divided by a plurality of partition walls 212. A volume of the pressure generation chamber 211 is changed by the piezoelectric element 100.

First communication paths 213 and second communication paths 214 are formed in end portions in a +Y-axis direction of the pressure generation chambers 211 in the channel formation substrate 210. The first communication path 213 is formed to have an opening area smaller by reduction of the end portion in the +Y-axis direction of the pressure generation chamber 211 from the X-axis direction. For example, a size of the second communication path 214 in the X-axis direction is the same as a size of the pressure generation chamber 211 in the X-axis direction. A third communication path 215 communicating with the plurality of second communication paths 214 is formed in the +Y-axis direction of the second communication paths 214. The third communication path 215 forms a part of a manifold 216. The manifold 216 serves as a common liquid chamber for the pressure generation chambers 211. Thus, a supply channel 217 including the first communication paths 213, the second communication paths 214, and the third communication path 215, and the pressure generation chambers 211 are formed in the channel formation substrate 210. The supply channel 217 communicates with the pressure generation chambers 211 and supplies a liquid to the pressure generation chambers 211.

The nozzle plate 220 is provided on one surface of the channel formation substrate 210. For example, a material for the nozzle plate 220 is stainless steel (steel use stainless: SUS). The nozzle plate 220 is bonded to the channel formation substrate 210 by, for example, an adhesive or a heat-welded film. A plurality of nozzle holes 222 are formed in the nozzle plate 220 along the X axis. The nozzle hole 222 communicates with the pressure generation chamber 211 and ejects the liquid.

The vibrating plate 230 is provided on the other surface of the channel formation substrate 210. The vibrating plate 230 includes, for example, a silicon oxide layer 232 provided on the channel formation substrate 210 and a zirconium oxide layer 234 provided on the silicon oxide layer 232.

For example, the piezoelectric element 100 is provided on the vibrating plate 230. A plurality of piezoelectric elements 100 are provided. For convenience, in FIG. 11, members of the piezoelectric element 100 other than the first electrode 10, the piezoelectric layer 20, and the interconnect 70 are not illustrated.

In the liquid ejection head 200, the vibrating plate 230 and the first electrode 10 are displaced by deformation of the piezoelectric layer 20 having electromechanical conversion characteristics. That is, in the liquid ejection head 200, the vibrating plate 230 and the first electrode 10 substantially function as a vibrating plate. The vibrating plate 230 may be omitted, and only the first electrode 10 may function as the vibrating plate. When the first electrode 10 is directly provided on the channel formation substrate 210, it is preferable to protect the first electrode 10 by an insulating protective film or the like so that the first electrode 10 is not brought into contact with the liquid.

The protective substrate 240 is bonded to the vibrating plate 230 by an adhesive (not shown). A through hole 242 is formed in the protective substrate 240. In the illustrated example, the through hole 242 penetrates the protective substrate 240 in the Z-axis direction. The through hole 242 communicates with the third communication path 215. The through hole 242 and the third communication path 215 form the manifold 216 serving as the common liquid chamber for each of the pressure generation chambers 211. Further, in the protective substrate 240, a through hole 244 that penetrates the protective substrate 240 in the Z-axis direction is formed. An end portion of the interconnect 70 is located in the through hole 244.

An opening portion 246 is formed in the protective substrate 240. The opening portion 246 is a space to prevent inhibition of driving of the piezoelectric elements 100. The opening portion 246 may be sealed or not.

The circuit board 250 is provided on the protective substrate 240. The circuit board 250 includes a semiconductor integrated circuit (IC) for driving the piezoelectric elements 100. The circuit board 250 and the interconnect 70 are electrically coupled via a coupling interconnect (not shown).

The compliance substrate 260 is provided on the protective substrate 240. The compliance substrate 260 includes a sealing layer 262 provided on the protective substrate 240 and a fixing plate 264 provided on the sealing layer 262. The sealing layer 262 is a layer for sealing the manifold 216. For example, the sealing layer 262 has flexibility. A through hole 266 is formed in the fixing plate 264. The through hole 266 penetrates the fixing plate 264 in the Z-axis direction. The through hole 266 is provided in a position overlapping with the manifold 216 as seen from the Z-axis direction.

### 3. Printer

Next, a printer according to the embodiment will be described with reference to the drawings. FIG. 12 is a perspective view schematically showing a printer 300 according to the embodiment.

The printer 300 is an inkjet printer. As shown in FIG. 12, the printer 300 includes a head unit 310. For example, the head unit 310 includes the liquid ejection heads 200. The number of liquid ejection heads 200 is not particularly limited. In the head unit 310, cartridges 312 and 314 forming a supply unit are detachably provided. A carriage 316 on which the head unit 310 is mounted is provided on a carriage shaft 322 attached to a device main body 320 to be movable in axial directions, and ejects a liquid supplied from a liquid supply unit.

Here, the liquid refers to any material of a substance in a liquid phase and includes materials in liquid states such as sols and gels. Further, the liquid includes not only the liquid as a state of a substance, but also a liquid with particles of a solid functional material such as pigments or metal particles dissolved, dispersed, or mixed in a solvent. Representative examples of the liquid include inks and liquid crystal emulsions. The term ink includes various types of liquid compositions such as general water-based ink, oil-based ink, gel ink, and hot-melt ink.

In the printer 300, a driving force of a drive motor 330 is transmitted to the carriage 316 via a plurality of gears (not shown) and a timing belt 332, and thereby, the carriage 316 with the head unit 310 mounted thereon is moved along the carriage shaft 322. The device main body 320 is provided with a conveyance roller 340 as a conveyance mechanism for moving a sheet S as a recorded medium such as paper relative to the liquid ejection head 200. The conveyance mechanism that conveys the sheet S is not limited to the conveyance roller, but may be a belt, a drum, or the like.

The printer 300 includes a printer controller 350 as a control unit that controls the liquid ejection head 200 and the conveyance roller 340. The printer controller 350 is electrically coupled to the circuit board 250 of the liquid ejection head 200. The printer controller 350 includes, for example, a random access memory (RAM) that temporarily stores various types of data, a read only memory (ROM) that stores control programs and the like, a central processing unit (CPU), and a drive signal generation circuit that generates drive signals to be supplied to the liquid ejection head 200.

The piezoelectric element 100 can be used in a wide range of applications, not limited to a liquid ejection head and a printer. For example, the piezoelectric element 100 is preferably used as a piezoelectric actuator of an ultrasonic motor, a vibrating dust removal device, a piezoelectric transformer, a piezoelectric speaker, a piezoelectric pump, and a pressure-electricity conversion device. Further, for example, the piezoelectric element 100 is preferably used as a piezoelectric sensor element of an ultrasonic detector, an angular velocity sensor, an acceleration sensor, a vibration sensor, a tilt sensor, a pressure sensor, a collision sensor, a human sensor, an infrared sensor, a terahertz sensor, a heat detection sensor, a pyroelectric sensor, and a piezoelectric sensor. Furthermore, the piezoelectric element 100 is preferably used as a ferroelectric element such as a ferroelectric memory (FeRAM), a ferroelectric transistor (FeFET), a ferroelectric calculation circuit (FeLogic), a and ferroelectric capacitor. In addition, the piezoelectric element 100 is preferably used as a voltage-controlled optical element of a wavelength converter, an optical waveguide, an optical path modulator, a refractive index control element, and an electronic shutter mechanism.

### 4. Experimental Example

### 4.1. First Experiment

### 4.1.1. Sample Preparation

### 4.1.1.1. Experimental Example 1

A surface of a single-crystal silicon substrate was thermally oxidized and an SiO₂ layer having a thickness of 1460 nm is formed. Then, a Zr film having a thickness of 400 nm was formed by a direct current (DC) sputtering method, and a ZrO₂ layer was formed by heat treatment at 850° C.

Then, as a first electrode, a Ti layer, a Pt layer, and an Ir layer having thicknesses of 20 nm, 80 nm, and 5 nm, respectively, were formed on the ZrO₂ layer by a DC sputtering method.

Then, simple solutions containing potassium 2-ethylhexanoate, sodium 2-ethylhexanoate, and niobium 2-ethylhexanoate were respectively synthesized. A mixed solvent of 2-ethylhexanoic acid and decane was used as an organic solvent. These simple solutions were mixed to obtain a KNN precursor solution.

Then, the prepared KNN precursor solution was applied onto an Ir layer by spin coating at 3000 rpm, dried at 180° C. for 2 minutes, degreased at 380° C. for 2 minutes, and fired by lamp annealing at 750° C. for 3 minutes. In this manner, a crystal layer was formed. A series of processes from the application of the KNN precursor solution to the firing of the KNN precursor layer was repeated to form a piezoelectric layer made of a KNN layer having a thickness of 2 μm.

Then, a moisture-resistant layer made of an HfO₂ layer having a thickness of 45 nm was formed on the KNN layer. The HfO₂ layer was formed by an ALD method using tetrakisdimethylaminohafnium (TDMAH) as a raw material, a film formation temperature of 85° C., and H₂O as an oxidizing agent.

In this manner, a sample in Experimental Example 1 was prepared.

### 4.1.1.2. Experimental Example 2

A sample in Experimental Example 2 was prepared in a similar manner as in Experimental Example 1 except that a film formation temperature of an HfO₂ layer was set to 150° C.

### 4.1.1.3. Experimental Example 3

A sample in Experimental Example 3 was prepared in a similar manner as in Experimental Example 1 except that the HfO₂ layer was not formed.

### 4.1.2. Experimental Conditions

### 4.1.2.1. SIMS

The samples in Experimental Examples 1 to 3 were subjected to SIMS. As the SISM, “IMS-7f sector type SIMS” manufactured by CAMECA was used, 15 keV Cs⁺ was used as a primary ion, raster scanned over a 100 μm square with a beam current of 10 nA, and negative secondary ions were detected from a center 33 μmφ. An electron gun was used to prevent charge-up. A surface of the HfO₂ layer was irradiated with an ion beam, and an amount of hydrogen entering the HfO₂ layer and the KNN layer was measured. A relative sensitivity factor (RSF) was determined based on an intensity detected by the SIMS as described in “1.2. SIMS”, and a water concentration was determined based on the relative sensitivity factor.

### 4.1.2.2. Leak Current Measurement

In the samples corresponding to Experimental Examples 1 to 3, before forming the HfO₂ layer, a Pt layer having a thickness of 50 nm was formed on the KNN layer of the sample by a DC sputtering method. Thereafter, the HfO₂ layer was formed. A voltage was applied between the first electrode and the Pt layer on the KNN layer using a semiconductor parameter analyzer, and a leak current was measured.

### 4.1.3. Experimental Results

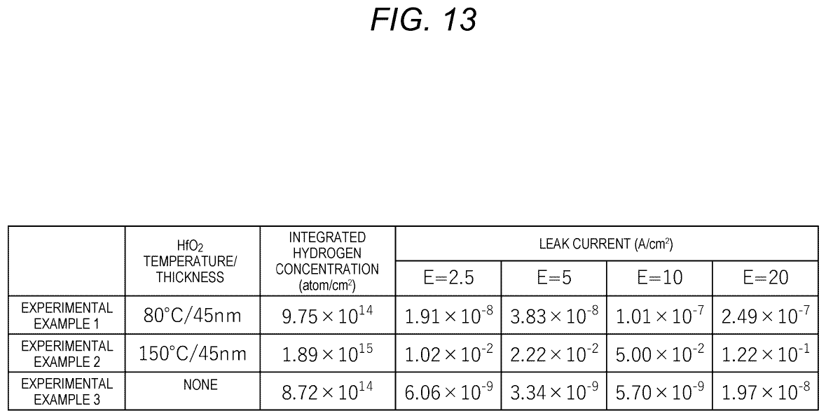

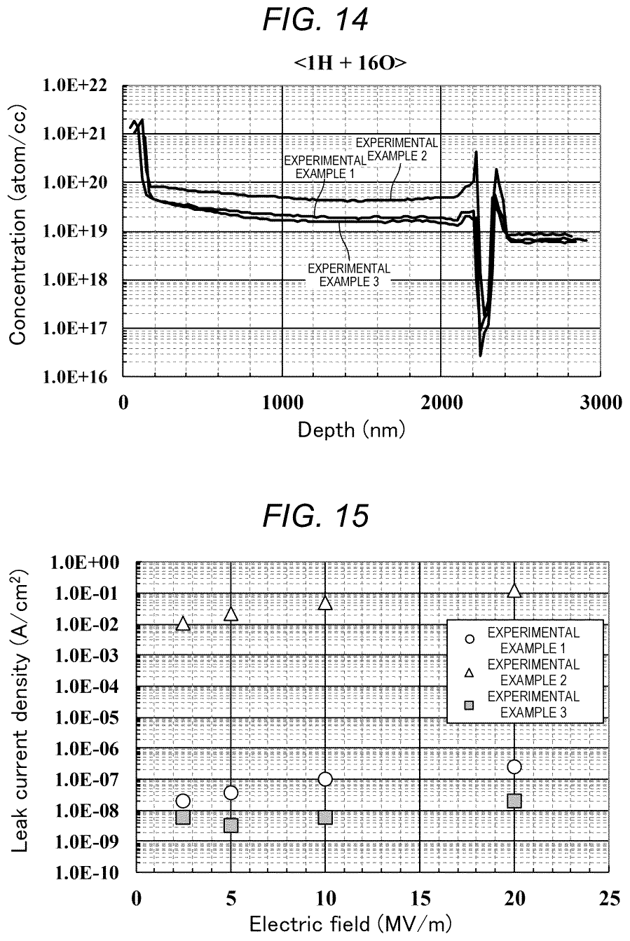

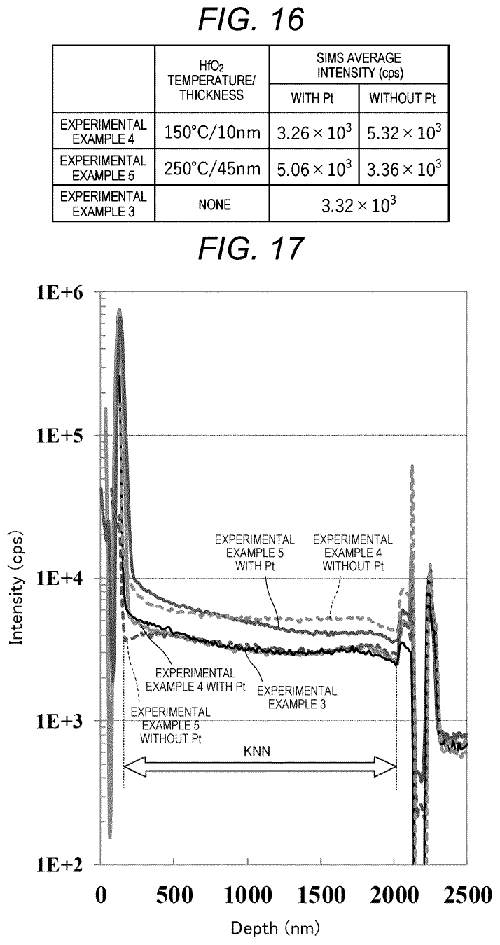

FIG. 13 is a table showing results of the SIMS and the leak current measurement in Experimental Examples 1 to 3. FIG. 14 is a graph showing results of the SIMS in Experimental Examples 1 to 3. FIG. 15 is a graph showing results of the leak current measurement in Experimental Examples 1 to 3. An integrated hydrogen concentration in FIG. 13 is calculated based on an integrated intensity in a range of 50 nm or more and 300 nm or less from a surface of the KNN layer based on a profile in FIG. 14. FIG. 15 is a plot of the leak current shown in FIG. 13. In FIG. 13, “E” indicates an applied electric field in units of MV/m.

As shown in FIGS. 13 to 15, in Experimental Example 1 in which the integrated hydrogen concentration was 9.75×10¹⁴ atom/cm², the leak current was smaller than that in Experimental Example 2 in which the integrated hydrogen concentration was 1.89×10¹⁵ atom/cm². In Experimental Example 3 in which the integrated hydrogen concentration was lower than that in Experimental Example 1, the leak current was smaller than that in Experimental Example 1. It was found that the leak current can be reduced when the integrated hydrogen concentration is low.

### 4.2. Second Experiment

### 4.2.1. Sample Preparation

### 4.2.1.1. Experimental Example 4

As in Experimental Example 1 described above, after forming up to the KNN layer, a Pt layer having a thickness of 50 nm was formed on the KNN layer of a sample by the DC sputtering method. Then, a moisture-resistant layer made of an HfO₂ layer having a thickness of 10 nm was formed on the KNN layer. The HfO₂ layer was formed by an ALD method using TDMAH as a raw material, a film formation temperature of 150° C., and H₂O as an oxidizing agent. Experimental Example 4 has a region where a Pt layer is formed above a KNN layer and a region where no Pt layer is formed above the KNN layer.

In this manner, a sample in Experimental Example 4 was prepared.

### 4.2.1.2. Experimental Example 5

A sample in Experimental Example 5 was prepared in a similar manner as in Experimental Example 4 except that a thickness of the HfO₂ layer was 45 nm, a film formation temperature was 250° C., and an oxidizing agent was O₃.

### 4.2.2. Experimental Method

SIMS was performed on the samples in Experimental Examples 4 and 5 by a similar method as the method described in the first experimental example described above. In this experiment, a hydrogen concentration is not obtained, but an intensity measured in this experiment correlates with the hydrogen concentration. In each of Experimental Examples 4 and 5, the SIMS was performed on a region where the Pt layer was formed above the KNN layer and a region where no Pt layer was formed above the KNN layer.

### 4.2.3. Experimental Results

FIG. 16 is a table showing results of the SIMS in Experimental Examples 4 and 5. FIG. 17 is a graph showing results of the SIMS in Experimental Examples 4 and 5. FIGS. 16 and 17 also show values in Experimental Example 3. “SIMS average intensity” in FIG. 16 is an average in a range of 500 nm to 1500 nm from a surface of a sample, calculated based on values in the graph in FIG. 17. In FIGS. 16 and 17, in each of Experimental Examples 4 and 5, the result for the region where the Pt layer is formed above the KNN layer is indicated as “with Pt”, and the result for the region where no Pt layer is formed above the KNN layer is indicated as “without Pt”.

As shown in FIGS. 16 and 17, in a range of the KNN layer, in Experimental Example 4, an intensity in the case of “with Pt” was smaller than an intensity in the case of “without Pt”. This is because, in the case of “with Pt”, diffusion of hydrogen based on the oxidizing agent H₂O into the KNN layer is prevented by the Pt layer.

On the other hand, in the range of the KNN layer, in Experimental Example 5, an intensity in the case of “with Pt” was greater than an intensity in the case of “without Pt”. This is considered to be because hydrogen taken into the Pt layer during the producing diffused from the Pt layer to the KNN layer due to a film formation temperature when forming an HfO₂ layer.

Therefore, as described in “1.3. Production method” above, it can be seen that when the Pt layer is formed after the HfO₂ layer is formed, hydrogen taken into the Pt layer can be prevented from diffusing from the Pt layer to the KNN layer due to the film formation temperature when the HfO₂ layer is formed.

### 4.3. Third Experiment

### 4.3.1. Sample Preparation

### 4.3.1.1. Experimental Example 6

A surface of a single-crystal silicon substrate was thermally oxidized and an SiO₂ layer having a thickness of 1460 nm is formed. Then, a moisture-resistant layer made of an HfO₂ layer having a thickness of 45 nm was formed on the SiO₂ layer. The HfO₂ layer was formed by an ALD method using TDMAH as a raw material, a film formation temperature of 85° C., and H₂O as an oxidizing agent.

In this manner, a sample in Experimental Example 6 was prepared.

### 4.3.1.2. Experimental Example 7

A sample in Experimental Example 7 was prepared in a similar manner as in Experimental Example 6 except that a film formation temperature in the ALD method was set to 150° C.

### 4.3.1.3. Experimental Example 8

A sample in Experimental Example 8 was prepared in a similar manner as in Experimental Example 6 except that the HfO₂ layer was not formed.

### 4.3.2. Experimental Method

After the samples in Experimental Examples 6 to 8 were exposed to heavy water vapor at a temperature of 80° C. and a humidity of 100%, SIMS was performed on the sample in Experimental Examples 6 to 8 by a similar method as described in the first experimental example.

### 4.3.3. Experimental Results

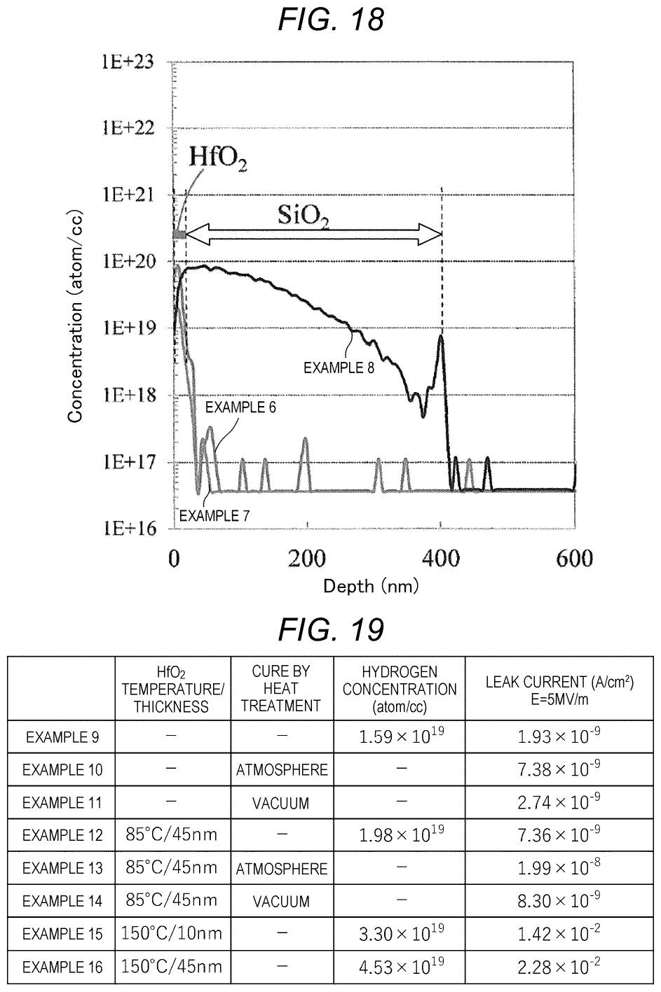

FIG. 18 is a graph showing results of the SIMS in Experimental Examples 6 to 8. As shown in FIG. 18, in Experimental Examples 6 and 7 in which the HfO₂ layer was formed, a concentration of deuterium in the SiO₂ layer was lower than that in Experimental Example 8 in which the HfO₂ layer was not formed. In Experimental Examples 6 and 7, in a range of a distance of 22 nm or less from a surface of the HfO₂ layer, a concentration of deuterium was 1/10 of that at a surface of the moisture-resistant layer. In Experimental Examples 6 and 7, the concentration of deuterium in the HfO₂ layer was higher than a concentration of deuterium in SiO₂. Accordingly, it was found that deuterium was trapped in the HfO₂ layer. No large difference was observed in Experimental Examples 6 and 7.

### 4.4. Fourth Experiment

### 4.4.1. Sample Preparation

After forming up to the KNN layer as in Experimental Example 1 described above, an IrO₂ layer and a Pt layer were formed in this order on the KNN layer by sputtering.

Then, an HfO₂ layer was formed by the ALD method. In the ALD method, H₂O was used as the oxidizing agent, and as shown in FIG. 19, a film formation temperature was set to 85° C. or 150° C., and a thickness of the HfO₂ layer was set to 45 nm or 10 nm. In Experimental Examples 9 to 11, the HfO₂ layer is not formed.

Then, a permanent resist as an organic insulating layer was formed by spin coating, drying, exposure, development, and curing. As the permanent resist, TMMR manufactured by Tokyo Ohka Kogyo Co., Ltd. was used. The curing was performed by heating at 190° C. for 1 hour. As shown in FIG. 19, the curing was performed in the atmosphere or in vacuum. Then, an Au layer was formed as an interconnect by sputtering. In Experimental Examples 9, 12, 15, and 16, the organic insulating layer and the interconnect are not formed.

In this manner, samples in Experimental Examples 9 to 16 were prepared.

### 4.4.2. Experimental Method

SIMS was performed on the samples in Experimental Examples 9, 12, 15, and 16 by a similar method as the method described in the first experimental example described above. Then, a hydrogen concentration at a position of ½ of a thickness of a KNN layer was obtained.

Further, a leak current in Experimental Examples 9 to 16 was measured by a similar method as the method described in the first experimental example.

### 4.4.3. Experimental Results

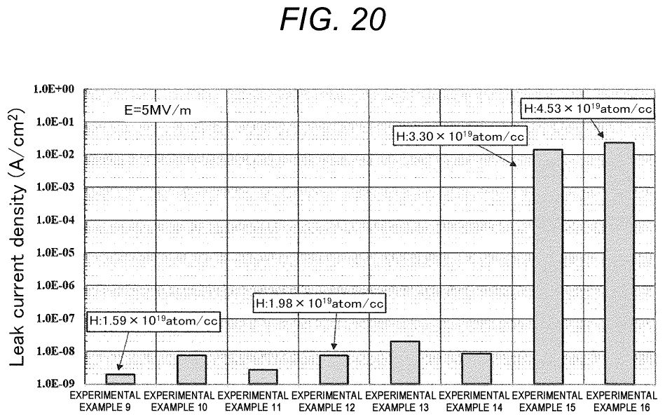

FIG. 19 is a table showing experimental results in Experimental Examples 9 to 16. FIG. 20 is a graph showing experimental results in Experimental Examples 9 to 16. In FIGS. 19 and 10, the leak current is a value when an electric field of 5 MV/m is applied.

As shown in FIGS. 19 and 20, by comparing Experimental Examples 13 and 14, it was found that when the HfO₂ layer having a thickness of 45 nm was formed at a film formation temperature of 85° C., the leak current was smaller when an organic insulating layer was cured in vacuum than when the organic insulating layer was cured in the atmosphere.

The above embodiment and modifications are examples, and the present disclosure is not limited thereto. For example, the embodiment and modifications may be combined as appropriate.

The present disclosure includes substantially the same configurations as the configurations described in the embodiment, such as a configuration having the same function, method, and result and a configuration having the same object and effect. The present disclosure includes a configuration in which a non-essential portion of the configuration described in the embodiments is replaced. The present disclosure includes a configuration capable of achieving the same function and effect or a configuration capable of achieving the same object as the configuration described in the embodiments. The present disclosure includes a configuration obtained by adding a known technique to the configuration described in the embodiments.

The following configurations are derived from the above-described embodiments and the modifications.

A piezoelectric element according to an aspect includes: a first electrode provided above a substrate; a piezoelectric layer provided above the first electrode; a second electrode provided above the piezoelectric layer; and a moisture-resistant layer covering at least a part of the piezoelectric layer, and when secondary ion mass spectrometry is performed on the piezoelectric layer, a hydrogen concentration calculated based on an integrated intensity in a range of 50 nm or more and 300 nm or less from a surface of the piezoelectric layer is 1.50×10¹⁵ atom/cm² or less.

According to the piezoelectric element, it is possible to improve moisture resistance while ensuring insulation properties of the piezoelectric layer.

In the piezoelectric element according to the aspect, the hydrogen concentration may be 1.00×10¹⁵ atom/cm² or less.

According to the piezoelectric element, the insulation properties of the piezoelectric layer can be further enhanced.

In the piezoelectric element according to the aspect, the hydrogen concentration may be 9.75×10¹⁴ atom/cm² or less.

According to the piezoelectric element, the insulation properties of the piezoelectric layer can be further enhanced.

The piezoelectric element according to the aspect may further include: a third electrode provided above the second electrode and electrically coupled to the second electrode, and a material for the second electrode may be a metal oxide, and a material for the third electrode may be a noble metal.

According to the piezoelectric element, resistance of an electrode including the second electrode and the third electrode can be reduced.

The piezoelectric element according to the aspect may include a portion in which the second electrode, the moisture-resistant layer, and the third electrode are stacked in this order from a piezoelectric layer side.

According to the piezoelectric element, the second electrode can reduce etching damage or contamination to the piezoelectric layer when the contact hole is formed in the moisture-resistant layer.

In the piezoelectric element according to the aspect, the moisture-resistant layer may be a layer formed by atomic layer deposition using ozone as an oxidizing agent.

According to the piezoelectric element, when the moisture-resistant layer is formed, hydrogen taken into the third electrode can be prevented from diffusing into the piezoelectric layer.

In the piezoelectric element according to the aspect, the moisture-resistant layer may be a layer formed by atomic layer deposition using water as an oxidizing agent.

According to the piezoelectric element, a dense moisture-resistant layer can be formed.

In the piezoelectric element according to the aspect, when the piezoelectric element is exposed to an atmosphere having a temperature of 80° C. and a humidity of 100% for 24 hours and then secondary ion mass spectrometry is performed on the moisture-resistant layer, a hydrogen concentration at a distance of 22 nm or less from a surface of the moisture-resistant layer may be 1/10 of a hydrogen concentration in the surface of the moisture-resistant layer.

According to the piezoelectric element, moisture resistance can be improved.

In the piezoelectric element according to the aspect, the piezoelectric layer may include a complex oxide having a perovskite type structure containing potassium, sodium, and niobium.

According to the piezoelectric element, since the piezoelectric layer does not contain lead, it is environmentally friendly.

A liquid ejection head according to an aspect includes: the piezoelectric element according to the aspect; and a nozzle plate in which a nozzle hole is formed, and the substrate has a channel formation substrate in which a pressure generation chamber whose volume is changed by the piezoelectric element is formed, and the nozzle hole communicates with the pressure generation chamber.

A printer according to an aspect of the present disclosure includes: the liquid ejection head according to the aspect; a conveyance mechanism configured to move a recorded medium relative to the liquid ejection head; and a control unit configured to control the liquid ejection head and the conveyance mechanism.

What is claimed is:

1. A piezoelectric element comprising:
a first electrode provided above a substrate;
a piezoelectric layer provided above the first electrode;
a second electrode provided above the piezoelectric layer; and
a moisture-resistant layer covering at least a part of the piezoelectric layer, wherein
when secondary ion mass spectrometry is performed on piezoelectric layer, the a hydrogen concentration calculated based on an integrated intensity in a range of 50 nm or more and 300 nm or less from a surface of the piezoelectric layer is 1.50×10¹⁵ atom/cm² or less.

2. The piezoelectric element according to claim 1, wherein
the hydrogen concentration is 1.00×10¹⁵ atom/cm² or less.

3. The piezoelectric element according to claim 1, wherein
the hydrogen concentration is 9.75×10¹⁴ atom/cm² or less.

4. The piezoelectric element according to claim 1, further comprising:
a third electrode provided above the second electrode and electrically coupled to the second electrode, wherein
a material for the second electrode is a metal oxide, and
a material for the third electrode is a noble metal.

5. The piezoelectric element according to claim 4, further comprising:
a portion in which the second electrode, the moisture-resistant layer, and the third electrode are stacked in this order from a piezoelectric layer side.

6. The piezoelectric element according to claim 5, wherein
the moisture-resistant layer is a layer formed by atomic layer deposition using ozone as an oxidizing agent.

7. The piezoelectric element according to claim 5, wherein
the moisture-resistant layer is a layer formed by atomic layer deposition using water as an oxidizing agent.

8. The piezoelectric element according to claim 1, wherein
when the piezoelectric element is exposed to an atmosphere having a temperature of 80° C. and a humidity of 100% for 24 hours and then secondary ion mass spectrometry is performed on the moisture-resistant layer, a hydrogen concentration at a distance of 22 nm or less from a surface of the moisture-resistant layer is 1/10 of a hydrogen concentration in the surface of the moisture-resistant layer.

9. The piezoelectric element according to claim 1, wherein
the piezoelectric layer includes a complex oxide having a perovskite type structure containing potassium, sodium, and niobium.

10. A liquid ejection head comprising:
the piezoelectric element according to claim 1; and
a nozzle plate in which a nozzle hole is formed, wherein
the substrate has a channel formation substrate in which a pressure generation chamber whose volume is changed by the piezoelectric element is formed, and
the nozzle hole communicates with the pressure generation chamber.

11. A printer comprising:
the liquid ejection head according to claim 10;
a conveyance mechanism configured to move a recorded medium relative to the liquid ejection head; and
a control unit configured to control the liquid ejection head and the conveyance mechanism.
